(19) United States
(12) Patent Application Publication
(10) Pub. No.: US 2003/0011971 A1
(43) Pub. Date: Jan. 16, 2003

(54) Keyboard unit

(76) Inventors: Toshiharu Suzuki, Chiba-shi (JP); Masato Mizuno, Chiba-shi (JP)

Correspondence Address: ADAMS & WILKS, 31st Floor, 50 Broadway, New York, NY, 10004, US

(21) Appl. No.: 10/131,641

(22) Filed: Apr. 23, 2002

(30) Foreign Application Priority Data
Apr. 26, 2001 (JP) 2001-129893

(51) Int. Cl. H05K 5/00

(52) U.S. Cl. 361/680

(57) ABSTRACT

To provide a keyboard unit keeping portability and improving facility of operation. The invention is a keyboard unit connected to an information terminal and has plural keys for performing character input to the information terminal, and the keyboard unit integrates with the information terminal at the state that at least lower side area than a display screen of the information terminal is packed in.

### BACKGROUND OF THE INVENTION

1. Field of the Invention

The present invention relates to a keyboard unit attached at an information terminal such as a PDA (Personal Digital Assistant) for performing character input by a keyboard.

2. Description of the Related Art

An electronic pocketbook, a PDA, etc. have been used hitherto as a portable information terminal. In such the portable information terminal, for example, PDA loading palm OS, input of character is performed by inputting on an operation screen by handwriting using a pen and the like. Because of that, there is the problem that input of character is comparatively troublesome and it takes long time.

To solve such a problem, an ultra-small sheet type keyboard used by bonding at an area of a screen, a keyboard unit used by being connected to an information terminal, etc. are proposed.

However, the former sheet type keyboard is used by being bonded at an operation screen, and it has limitation in key pitch and key size, and has a large part with handwriting input system because the keyboard is too small though portability of the information terminal is kept, thereby it has the problem that operation is difficult and input miss increases.

On the other hand, the latter keyboard unit is used by being connected to the information terminal, and it has the problem that good portability being one of large characteristic of the information terminal cannot be kept because the whole size becomes large though facility of operation is improved as the keyboard is comparatively large.

In view of such a situation, an object of the invention is to provide a keyboard unit keeping portability and improving facility of operation.

### SUMMARY OF THE INVENTION

The first embodiment of the invention to solve the above-mentioned problem is a keyboard unit connected to an information terminal and having plural keys for performing character input to the information terminal, wherein at least a part of the information terminal is packed in the keyboard unit, and the keyboard unit is integrated with the information terminal so that the keys are arranged facing surface area of the information terminal.

The second embodiment of the invention is a keyboard unit, wherein the keyboard unit is integrated with the information terminal at the state that the keyboard unit is packed into input portion by handwriting area of the information terminal in the first embodiment.

The third embodiment is a keyboard unit, wherein the keys include a push button for accessing various kinds of application which the information terminal has, and a function key performing equal operation as a touch button in the input portion by handwriting area in the first embodiment or the second embodiment.

The fourth embodiment of the invention is a keyboard unit, further comprising: a keyboard body having the keys; and a case member in which the keyboard body is fixed, and an inserting portion for inserting the information terminal is defined.

Since the lower side of the operation screen of the PDA body is packed in, portability is kept even at the state connecting the keyboard to the information terminal, and facility of operation improves because the area of the keyboard can be made comparatively large.

### BRIEF DESCRIPTION OF THE DRAWINGS

FIGS. 1A and 1B are a perspective assembled view showing a keyboard unit according to a mode for carrying out the invention, FIG. 1A is a upper side view showing the keyboard unit, FIG. 1B is a back side view showing the keyboard unit.

FIG. 2 is a perspective exploded view showing the keyboard unit according to the mode for carrying out-the invention.

FIG. 3 is a schematic illustration showing an example of an information terminal.

FIG. 4 is a perspective view showing a using state of the keyboard unit according to the mode for carrying out the invention.

FIG. 5 is a perspective view showing the keyboard unit according to another mode for carrying out the invention.

FIG. 6 is a perspective view showing the keyboard unit according to another mode for carrying out the invention.

### DESCRIPTION OF THE PREFERRED EMBODIMENT

The invention will be described in detail by referring to a mode for carrying out.

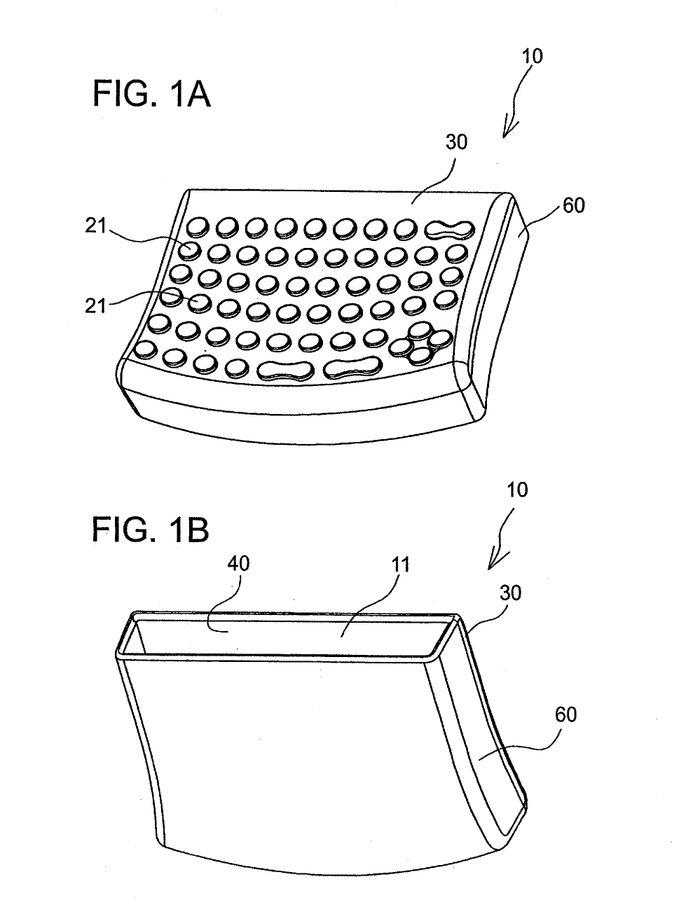

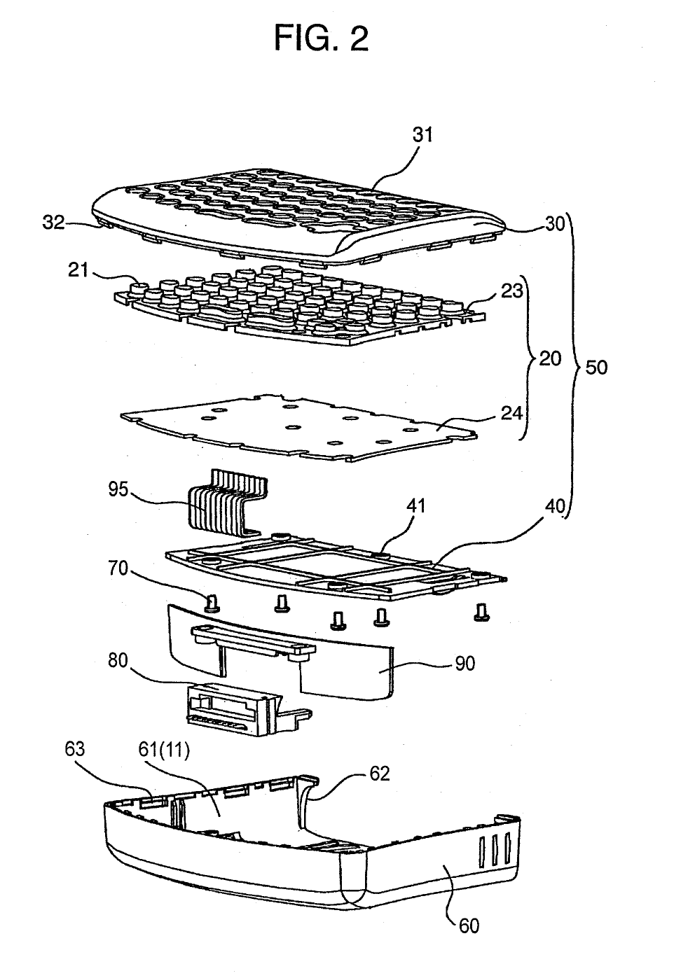

FIGS. 1A and 1B are a perspective assembled view of a keyboard unit according to a mode for carrying out the invention, and FIG. 2 is a perspective exploded view of the keyboard unit.

A keyboard unit 10 of the invention has a keyboard member 20 having key portions 21, a keyboard body 50 consisting of a first case 30 having the keyboard member 20 built-in and a second case 40, and a third case 60 being fixed engaging with the keyboard body 50 and having a hollowed portion 61 defining an inserting portion 11 packing a part of an information terminal of PDA etc., as shown in the figures.

The keyboard member 20 consists of a keypad member 23 having plural key portions 21 and a circuit board 24 arranged at rear face of the keypad member 23, as shown in FIG. 2. A conductive portion is provided at rear face of the key portions 21, and on the circuit board 24 facing to the conductive portion, a contact-point pattern is formed. It is constituted that the conductive portion of rear face of the key portions 21 contacts the facing contact-point pattern to conduct when the key portions 21 are pressed. The circuit board 24 is with a circuit for processing signal input by pressing each key portion 21.

The first case 30 has a hollowed portion being large so as to have the keyboard member 20 built-in, and has through-holes 31 at positions corresponding to the key portions 21 respectively at operation face side. At side face of the first case 30, engaging projections 32 projecting to opposite side of the operation face and engaging with the third case 60.

The second case 40 is roughly flat plate shape, and has plural inserting holes 41 where screw members 70 for fixing to the first case 30 are inserted. The keyboard member 20 is arranged in the hollowed portion of the first case 30 so that a part of each key portion 21 projects from each through-hole 31, and the second case 40 is fixed to the first case 30 from the rear face side by the screw members 70, thereby a keyboard body 50 is formed by being built between the first case 30 and the second case 40.

The third case 60 has a hollowed portion 61 defining the inserting portion 11 packing the information terminal, and has an opening portion 62 for inserting the information terminal at one side-face side. Engaging hollowed portions 63 for engaging with engaging projections 32 provided at the first case 30 are provided at each side face. At the neighborhood of side face of the opposite side of the opening portion 62 of the third case 60, a connector 80 for electrically connecting the information terminal is fixed by a fixing member 90 defining the bottom face of the inserting portion 11. The connector 80 is connected to the circuit board 24 through a cable 95.

In assembly order of the keyboard unit 10 of such a constitution, first the keyboard member 20 is arranged in the first case 30, and the second case 40 is fixed to the first case 30 by the screw members 70 so as to become the keyboard body 50. After that, the engaging projections 32 of the first case 30 are engaged and fixed with the engaging hollowed portions 63 of the third case 60 fixing the connector 80, the fixing member 90, etc. so as to become the keyboard unit 10.

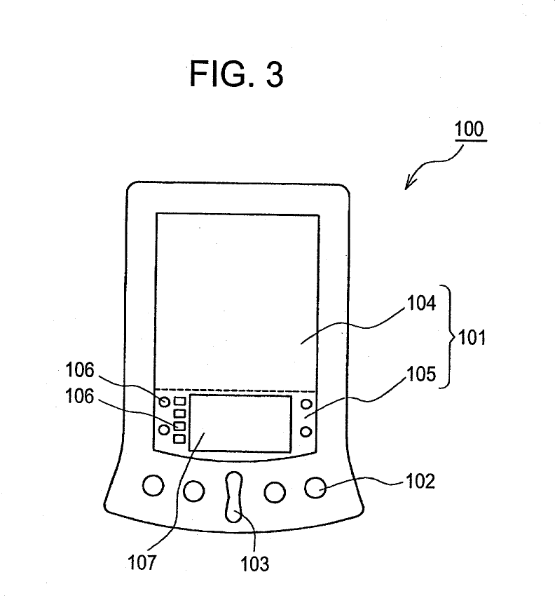

On the other hand, the information terminal 100 loaded on such the keyboard unit 10 is a PDA loading palm OS, for example, and has a display screen 101 consisting of an LCD and the like, a push button 102 for accessing various kinds of application, and a direction button 103 using for scrolling picture as shown in FIG. 3. The display screen 101 has a display area 104 displaying information and an operational area 105 performing various kinds of operations by pen operation and the like. The operational area 105 has, for example, touching buttons 106 for carrying out various kinds of function and a character input area 107 for inputting character by handwriting.

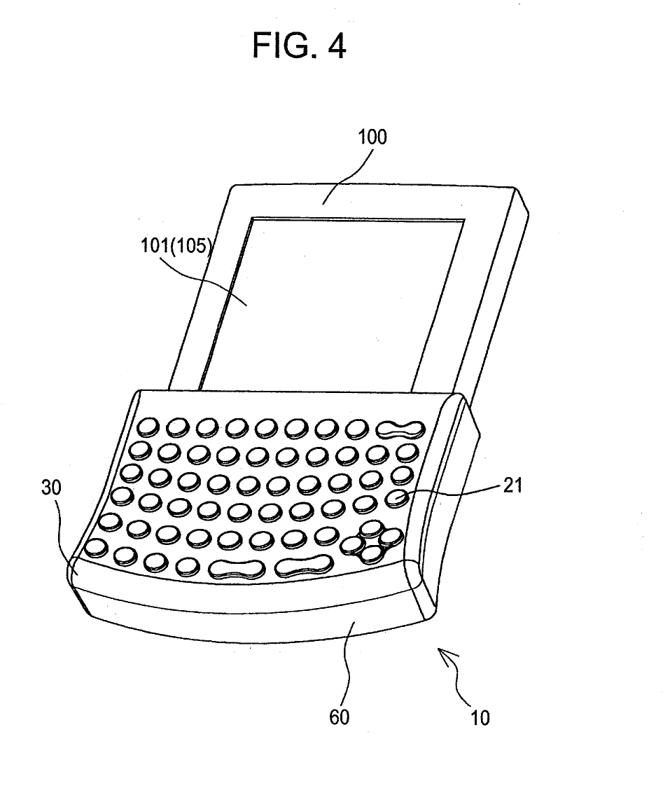

Such a keyboard unit 10 of the invention has size approximating size of the information terminal 100, and the information terminal 100 is packed in the inserting portion 11 to the operational area 105 of the display screen 101 and only the display area 104 is exposed as shown in FIG. 4. Only by inserting the information terminal 100 into the inserting portion 11, these are integrated and are connected electrically through the connector 80.

Thus, the whole size almost never changes as the size of the information terminal 100 even if the information terminal 100 is attached at the keyboard unit 10 of the invention. Therefore, portability is kept well even in the state that the keyboard unit 10 and the information terminal 100 are always connected. Further, since the size almost never changes, key input can be performed easily at the state being kept by the palm of the hand and the fingertip.

Further, because operation command input from the push button 102, the direction button 103, the touch button, etc. of the information terminal 100 are distributed to each key portion 21 of the keyboard member 20 by the electrical connection, character input independent on handwriting operation can be performed, and various kinds of application and the like can be carried out by key input from the keyboard member 20.

It is needed for the information terminal 100 to detect previously existence of the keyboard, to encode data sent to the operation command of the information terminal 100 from the keyboard through communication, and to install a software for operating and instructing.

As described above, the keyboard unit 10 of the invention consists of the first case 30, the second case 40, and the third case 60, the keyboard member 20 is built in the first case 30 and the second case 40 so as to constitute the integrated keyboard body 50. Because of that, by fixing the keyboard body 50 and the third case 60, the thickness of the inserting portion 11 defined between them can be changed only by the shape of the third case 60. Therefore, by exchanging only the third case 60 responding on kinds of information terminal in common with each part constituting the keyboard body 50, the keyboard unit corresponding to plural kinds of information terminal can easily be produced. Accordingly, production cost is reduced, and comparably low-priced keyboard unit is provided.

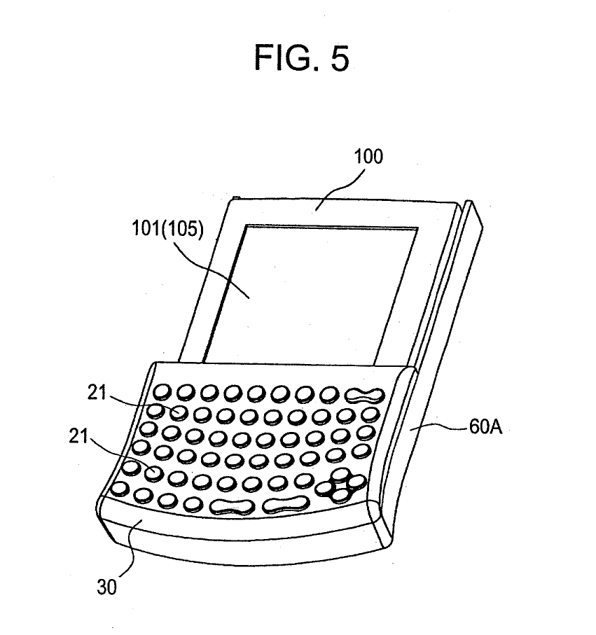

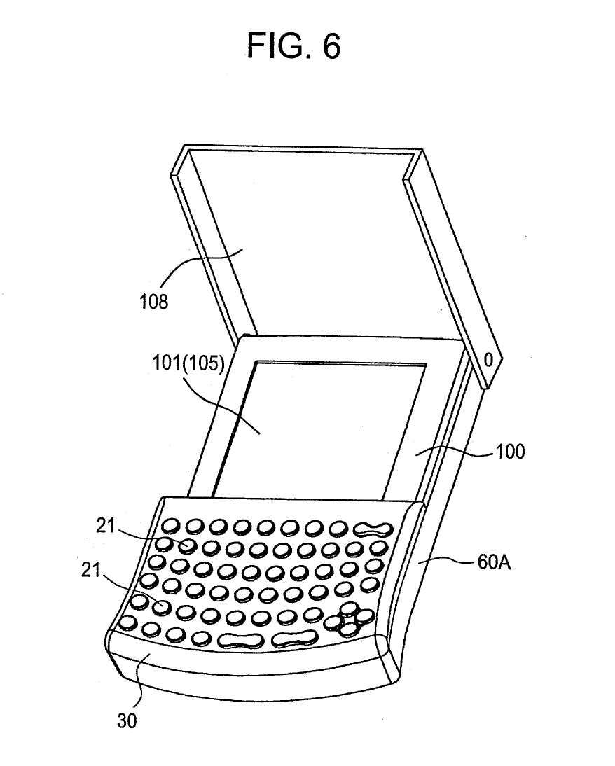

Although the keyboard 10 has shape packing the lower side of the display area 104 of the information terminal 100 in the mode for carrying out, at least display area of the screen of the information terminal may be exposed without limiting to this. For example, as shown in FIG. 5, the area of the third case 60 is made larger than the first case 30, and the rear of the information terminal 100 may be covered. Further, as shown in FIG. 6, a movable cover member 108 covering the display area 104 of the information terminal 100 may be provided. Thus, probability of the information terminal 100 is kept, facility of operation is improved, and protection of the information terminal 100 is designed.

As described above, since lower side than the display area of the information terminal is packed into the keyboard unit of the invention, the size of the unit is almost the same as the size of the information terminal itself so as to keep portability well. A user can key-input easily at the state holding by hand so as to improve sharply facility of operation.

What is claimed is:

1. A keyboard unit connected to an information terminal and having plural keys for performing character input to the information terminal,
wherein at least a part of the information terminal is packed in the keyboard unit, and the keyboard unit is integrated with the information terminal so that the keys are arranged facing surface area of the information terminal.

2. A keyboard unit according to claim 1,
wherein the keyboard unit is integrated with the information terminal at the state that the keyboard unit is packed into input portion by handwriting area of. the information terminal.

3. A keyboard unit according to claim 1,
wherein the keys include a push button for accessing various kinds of application which the information terminal has, and a function key performing equal operation as a touch button in the input portion by handwriting area.

4. A keyboard unit according to claim 1, further comprising: a keyboard body having the keys; and a case member in which the keyboard body is fixed at position facing to surface area of the information terminal, and an inserting portion for inserting the information terminal is defined.
